(19) United States
(12) Patent Application Publication
(10) Pub. No.: US 2022/0262750 A1
(43) Pub. Date: Aug. 18, 2022

(54) A Semiconductor Device and a Method Making the Same

(71) Applicant: ChangXin Memory Technologies, Inc., Hefei City (CN)

(72) Inventor: Ping-Heng Wu, Hefei City (CN)

(21) Appl. No.: 17/626,739

(22) PCT Filed: Jun. 19, 2020
(86) PCT No.: PCT/CN2020/097163

§ 371 Date: Jan. 12, 2022

(30) Foreign Application Priority Data
Dec. 2, 2019 (CN) 201911212672.8

(51) Int. Cl. H01L 23/00

(52) U.S. Cl. CPC H01L 24/05; H01L 24/03; H01L 2224/05011; H01L 2224/04042; H01L 2224/03614

(57) ABSTRACT

A semiconductor structure includes a supporting layer including a pad area; and a groove formed in the pad area of the supporting layer, wherein a bottom width of the groove is greater than a top width of the groove; and a pad disposed in the pad area on the supporting layer, wherein the pad is partially embedded in the groove. This structure can help to release the bonding pressure during the wire bonding process. When the pad is squeezed out, it can enter the air cavity, which can prevent the protective layer from being lifted up or cracked, and avoid the pad from overflowing. At the same time, the bonding wire squeezed into the air cavity during bonding process increases the contact area between the pad and the supporting layer, thereby enhancing the stability of the overall structure.

### TECHNICAL FIELD

This application relates to the field of semiconductor device manufacturing, in particular to a semiconductor structure and a manufacturing method thereof.

### BACKGROUND

In the existing process, when the wire bonding process is performed on the pad. Since the pad is generally made of soft aluminum, the solder pad will be quickly squashed under the bonding pressure from the bonding force during the wire bonding process, if the opening in the protective layer is too small or the wire is misaligned causing the bonding wire to be close to the protective layer, the underside of the solder pad will protrude out so to lift up or crack the protective layer, or the pad may overflow under pressure, thereby causing quality problems.

### SUMMARY

Based on this, it is necessary to provide a semiconductor structure and a manufacturing method thereof to address the above-mentioned issues.

The present application provides a semiconductor structure including: a supporting layer including a pad area, and a groove formed in the pad area of the supporting layer, wherein a bottom width of the groove is greater than a top width of the groove; and

a pad disposed in the pad area on the supporting layer, wherein the pad is partially embedded in the groove.

In the above semiconductor structure, by forming the supporting layer with grooves in the pad area under the pad, and by designing the bottom width of the groove greater than the top width of the groove, there is an air cavity in between the embedded pad in the groove and the side walls of the lower part of the groove. During the wire bonding process, even if the pad is flat and most of the pad is squeezed out under the action of the bonding pressure, the squeezed out pad will fill the air cavity, so to avoid lifting or cracking the protective layer and prevent the pad from overflowing, thereby ensuring the quality of the product. At the same time, because the pad will enter the air cavity during the wire bonding process, it will increase the contact area between the pad and the supporting layer. This will enhance the stability of the overall structure.

In one of the embodiments, the supporting layer is a single-layer structure.

In one of the embodiments, the supporting layer is a stacked structure, which includes: a first material layer, a second material layer, which is located on the upper surface of the first material layer, wherein the groove is formed in the second material layer.

In one of the embodiments, a longitudinal cross-sectional shape of the groove has a bottle shape or a trapezoid shape.

In one of the embodiments, an inclination angle of the sidewall of the groove relative to the upper surface of the supporting layer is 30°-65°.

In the above semiconductor structure, by limiting the inclination angle between the sidewall and the upper surface of the supporting layer to 30°˜65°, the pad can fill the air cavity during the wire bonding process, so that the contact area of the pad and supporting layer is maximized, which makes the overall structure the most stable.

In one of the embodiments, the supporting layer is a stacked structure, which includes: a first material layer, wherein a trench is formed in the first material layer; and a second material layer disposed on an upper surface of the first material layer, wherein a through hole penetrating in a thickness direction of the second material layer is formed in the second material layer, wherein a width of the trench is greater than a width of the through hole, wherein the trench interconnects with the through hole, and wherein the trench and the through hole jointly form the groove.

In one of the embodiments, the width of the trench is 1.5 to 6 times of the width of the through hole.

In one of the embodiments, the supporting layer is a stacked structure, and the supporting layer includes: a first material layer; a second material layer located on the upper surface of the first material layer; a third material layer located on the upper surface of the second material layer; wherein, a first through hole is formed in the third material layer penetrating in the thickness direction, and a second through hole is formed in the second material layer penetrating in the thickness direction; the width of the second through hole is greater than the width of the first through hole. The second through hole connects with the first through hole, and wherein the first through hole and the second through hole jointly form a part of the groove.

In one of the embodiments, the width of the second through hole is 1.5 to 6 times of the width of the first through hole.

In one of the embodiments, the semiconductor structure further includes: a protective layer located on the upper surface of the supporting layer and an upper surface of the pad; the protective layer has an opening which exposes the pad; a bonding wire, wherein one end of the bonding wire is disposed in the opening and wherein the bonding wire is connected with the pad.

The present invention also provides a method for manufacturing a semiconductor structure, which includes the following steps: forming a supporting layer, the supporting layer includes a pad area; forming a plurality of grooves in the pad area of the supporting layer, and the bottom width of the groove is greater than the width of the top of the groove; forming a pad in the pad area of the supporting layer, and the pad is partially embedded in the groove.

In the above-mentioned method for manufacturing the semiconductor structure, by forming the supporting layer with grooves in the pad area under the pad, and by designing the bottom width of the groove greater than the top width of the groove, there is an air cavity in between the embedded pad in the groove and the side walls of the lower part of the groove. During the wire bonding process, even if the pad is flat and most of the pad is squeezed out under the action of the bonding pressure, the squeezed out pad will fill the air cavity, so to avoid lifting or cracking the protective layer and prevent the pad from overflowing, thereby ensuring the quality of the product. At the same time, because the pad will enter the air cavity during the wire bonding process, it will increase the contact area between the pad and the supporting layer. This will enhance the stability of the overall structure.

In one of the embodiments, forming the supporting layer includes the following steps: forming a material layers, etching the material layer to form the grooves in the material layer.

In one of the embodiments, forming the supporting layer includes the following steps: forming the first material layer; forming a second material layer on the upper surface of the first material layer; etching the second material layer to form the grooves in the second material layer.

In one of the embodiments, forming the supporting layer includes the following steps: forming the first material layer; forming a second material layer on the upper surface of the first material layer; etching the second material layer to form a through hole in the second material layer that penetrates in a thickness direction of the second material layer; etching the first material layer from the through hole to form a trench, wherein a width of the trench is greater than a width of the through hole, wherein the trench interconnects with the through hole, and wherein the trench and the through hole jointly form the groove.

In one of the embodiments, forming the supporting layer includes the following steps: forming the first material layer; forming a second material layer on the upper surface of the first material layer; forming a third material layer on the upper surface of the second material layer; etching the third material layer to form a first through hole penetrating in the third material layer along the thickness direction; and

etching the second material layer from the first through hole to form a second through hole penetrating the second material layer in a thickness direction, wherein a width of the second through hole is greater than a width of the first through hole, wherein the second through hole interconnects with the first through hole, and wherein the first through hole and the second through hole jointly form the groove.

In one of the embodiments, after forming the solder pad, the following steps further include: forming a protective layer on the upper surface of the supporting layer and the upper surface of the pad, the protective layer covers the pad; forming an opening in the protective layer, and the opening exposes the pad; providing a bonding wire, and one end of the bonding wire is connected with the pad.

It should be understood that the above general description and the following detailed description are only exemplary and cannot limit the present disclosure.

### BRIEF DESCRIPTION OF THE DRAWINGS

By describing its exemplary embodiments in detail with reference to the accompanying drawings, the above and other objectives, features and advantages of the present disclosure will become more apparent.

FIG. 1 is a flowchart of the method for manufacturing a semiconductor structure in an embodiment of the present application;

FIGS. 2 to 19 are cross-sectional views of the structures at each step of the method according to some embodiments of the present application; among them, FIGS. 16 to 19 are also diagrams of different semiconductor structures according to another embodiment of the present application.

The reference numbers for parts in the figures are listed as: 10—supporting layer, 101—first material layer, 102—second material layer, 103—third material layer, 11—groove, 111—through hole, 112—trench, 113—first through hole, 114—second through hole, 12—pad, 13—protection layer, 131—opening, 14—bonding line, 15—air cavity, α—the inclination angle between the sidewall of the groove and the upper surface of the supporting layer.

### DETAILED DESCRIPTION OF THE PREFERRED EMBODIMENTS

In order to facilitate the understanding of this application, the following will make a more comprehensive description of this application with reference to related drawings. The preferred embodiment of the application is shown in the accompanying drawings. However, this application can be implemented in many different forms and is not limited to the embodiments described herein. On the contrary, the purpose of providing these embodiments is to make the disclosure of this application more thorough and comprehensive.

It should be noted that when an element is considered to be “connected” to another element, it may be directly connected to and integrated with another element, or there may be a centering element at the same time. The terms “installed”, “one end”, “the other end” and similar expressions used herein are for illustrative purposes only.

Unless otherwise defined, all technical and scientific terms used herein have the same meaning as commonly understood by those skilled in the technical field of this application. The terminology used in the specification of the application herein is only for the purpose of describing specific embodiments, and is not intended to limit the application. The term “and/or” as used herein includes any and all combinations of one or more related listed items.

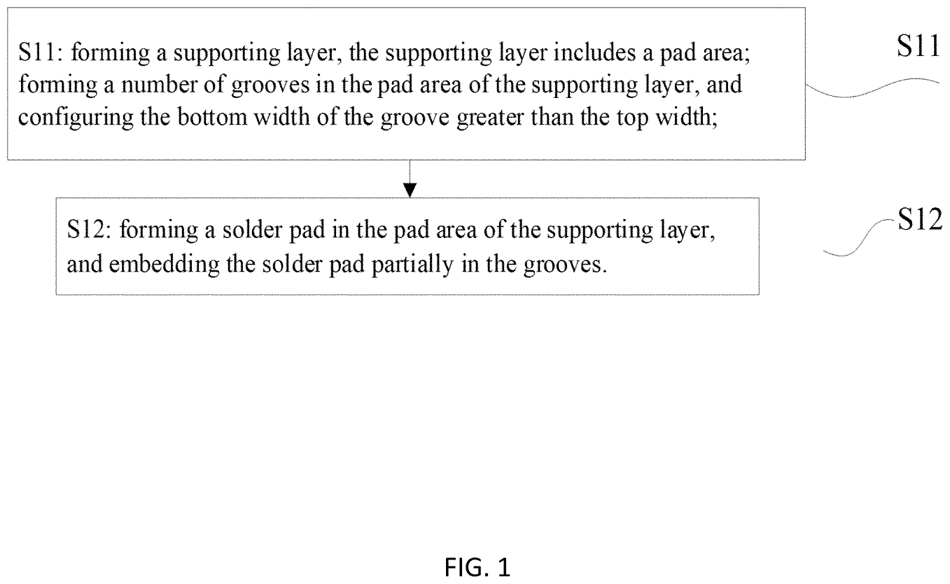

According to one embodiment of the present invention, as shown in FIG. 1, a method for manufacturing a semiconductor structure includes the following steps:

S11: forming a supporting layer, the supporting layer includes a pad area; and wherein a groove is formed in the pad area of the supporting layer, and wherein a bottom width of the groove is greater than a top width of the groove;

S12: forming a pad in the pad area of the supporting layer, and embedding the pad partially in the groove.

In this method for manufacturing the semiconductor structure, by forming a supporting layer with a plurality of grooves in the pad area under the pad, and by making the bottom width of each groove greater than the top width of the groove, there is an air cavity in between the embedded pad in the groove and the side walls of the lower part of the groove. During the wire bonding process, even if a pad is flat and most of the pad will be squeezed out under the action of the bonding pressure, the squeezed out pad will enter the air cavity to prevent the pad from overflowing, therefore the protective layer can be prevented from being lifted up or cracked, thereby ensuring the quality of the product; at the same time, because the pad will enter the air cavity during the wire bonding process, the pad and supporting layer will have their contact area increased so as to enhance the stability of the overall structure.

In an example, the supporting layer 10 may be formed on a substrate (not shown in the figures), and the substrate may be any substrate that can play a supporting role.

In an optional example, step S11 may include the following steps:

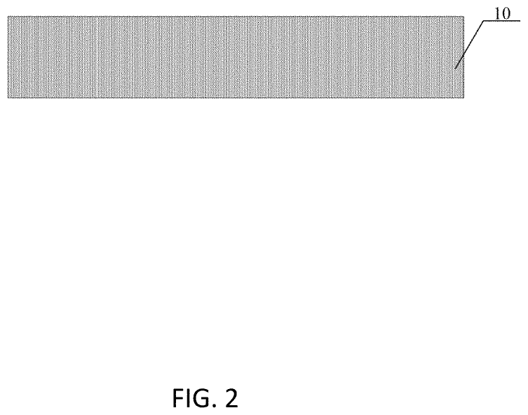

S111: forming a material layer, the material layer at this time is the supporting layer 10, as shown in FIG. 2; specifically, a physical vapor deposition process, a chemical vapor deposition process, or an atomic layer deposition process can be used to form the material layer; the material layer can include but not limited to at least one of a silicon oxide layer, a silicon nitride layer, a silicon oxynitride layer, a silicon carbonitride layer, a tungsten layer, a titanium layer, a titanium nitride layer, and a tantalum layer.

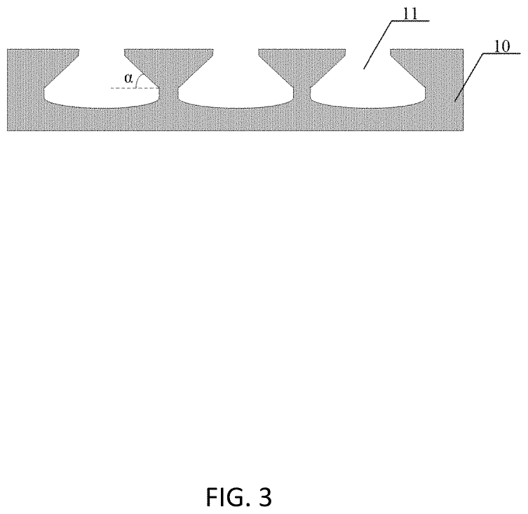

S112: the material layer is etched to form a groove 11 in the material layer, as shown in FIG. 3. Specifically, first, a patterned mask layer (not shown) can be formed on the upper surface of the material layer, the patterned mask layer can include but not limited to, a patterned photoresist layer; then, the material layer is photo exposed, developed, and then dry-etched based on the patterned mask layer, meanwhile reducing lower sidewall protection during the etching process, so results in lateral etching (under cut) to form a groove 11 in the material layer; finally, remove the patterned mask layer.

In an example, the depth of the groove 11 can be less than the thickness of the supporting layer 10, as shown in FIG. 3. At this time, the depth of the groove 11 can be set according to actual needs. For example, the depth of the groove 11 can be ⅓, ⅔ or ¾, etc. of the thickness of the supporting layer 10.

In an example, the longitudinal (perpendicular to substrate) cross-sectional shape of the groove 11 may be a bottle shape (as shown in FIG. 3), a trapezoid shape, or the like.

In an example, as shown in FIG. 3, the inclination angle α between the sidewall of the groove 11 and the upper surface of the supporting layer 10 may be 30°˜65°, specifically, it may be 30°, 40°, 50°, 60° or 65° and like. By limiting the inclination angle α of the sidewall of the groove 11 with the upper surface of the supporting layer 10 to be 30°˜65°, the pad 12 can fill the air cavity during the wire bonding process, so that the contact area of the pad 12 with the supporting layer 10 is maximized, the overall structure is most stable.

In another optional example, step S11 may include the following steps:

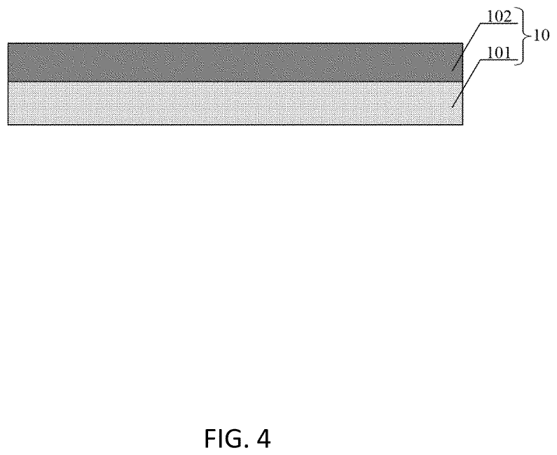

S111: forming a first material layer 101, as shown in FIG. 4; the first material layer 101 may be formed by a physical vapor deposition process, a chemical vapor deposition process, or an atomic layer deposition process; the first material layer 101 may include but is not limited to at least one of a silicon oxide layer, a silicon nitride layer, a silicon oxynitride layer, a silicon carbonitride layer, a tungsten layer, a titanium layer, a titanium nitride layer, and a tantalum layer;

S112: A second material layer 102 is formed on the upper surface of the first material layer 101, as shown in FIG. 4; the second material layer 102 may be formed by using a physical vapor deposition process, a chemical vapor deposition process, or an atomic layer deposition process. The material layer 102 may include but is not limited to at least one of a silicon oxide layer, a silicon nitride layer, a silicon oxynitride layer, a silicon carbonitride layer, a tungsten layer, a titanium layer, a titanium nitride layer, and a tantalum layer. The material of the second material layer 102 is different from the material of the first material layer 101, and under the same etching conditions, the second material layer 102 has a higher etch selection ratio than the first material layer 101, to ensure that the first material layer 101 can serve as an etch stop layer for the second material layer 102.

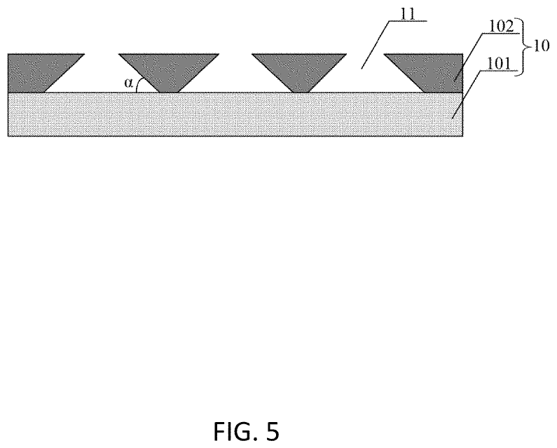

S113: The second material layer 102 is etched to form a groove 11 in the second material layer 102, as shown in FIG. 5. Specifically, first, forming a patterned mask layer on the upper surface of the second material layer 102 (not shown). The patterned mask layer may include but is not limited to a patterned photoresist layer; then, the second material layer 102 is dry-etched based on the patterned mask layer. During the etching process, since the first material layer 101 is an etch stop layer, after the second material layer 102 is etched through, the etching is continued for a certain period of time to create a lateral etching, so the groove 11 in the second material layer 102 is formed. Finally, remove the patterned mask layer.

In an example, the depth of the groove 11 may be less than or equal to the thickness of the second material layer 102. Preferably, as shown in FIG. 5, the depth of the groove 11 is equal to the thickness of the second material layer 102.

In an example, the longitudinal cross-sectional shape of the groove 11 may be a bottle shape or a trapezoid shape (as shown in FIG. 5) and so on.

In an example, as shown in FIG. 5, the inclination angle α between the sidewall of the groove 11 and the upper surface of the supporting layer 10 may be 30°˜65°, specifically, it may be 30°, 40°, 50°, 60° or 65° and so on. By limiting the inclination angle α between the sidewall of the groove 11 and the upper surface of the supporting layer 10 to be 30°˜65°, the pad 12 can fill the air cavity during the wire bonding process, so that the contact area of the pad 12 with the supporting layer 10 is maximized, so the overall structure is the most stable.

In another example, step S11 includes the following steps:

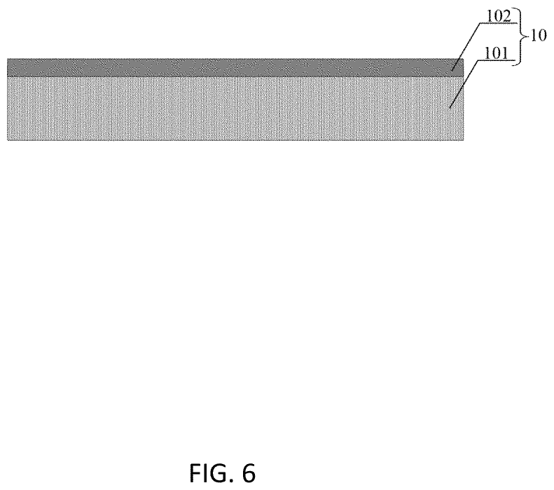

S111: forming a first material layer 101, as shown in FIG. 6; a physical vapor deposition process, a chemical vapor deposition process, or an atomic layer deposition process may be used to form the material layer of the first material layer 101; the first material layer 101 may include but not limited to at least one of a silicon oxide layer, a silicon nitride layer, a silicon oxynitride layer, a silicon carbonitride layer, a tungsten layer, a titanium layer, a titanium nitride layer, and a tantalum layer.

S112: a second material layer 102 is formed on the upper surface of the first material layer 101, as shown in FIG. 6; the second material layer 102 may be formed by a physical vapor deposition process, a chemical vapor deposition process, or an atomic layer deposition process. The material layer 102 may include but is not limited to at least one of a silicon oxide layer, a silicon nitride layer, a silicon oxynitride layer, a silicon carbonitride layer, a tungsten layer, a titanium layer, a titanium nitride layer, and a tantalum layer. The material of the second material layer 102 is different from the material of the first material layer 101, and under the same etching conditions, the first material layer 101 has a higher etching selection ratio than the second material layer 102.

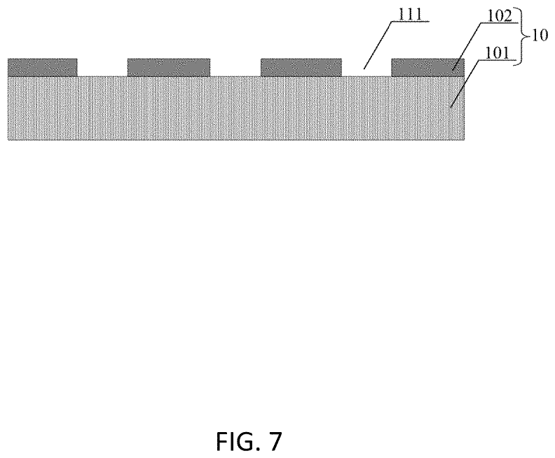

S113: the second material layer 102 is etched to form a through hole 111 penetrating in the thickness direction of the second material layer 102, as shown in FIG. 7. Specifically, first, a patterned mask layer (not shown) is formed on the upper surface of the second material layer 102. The patterned mask layer may include but is not limited to a patterned photoresist layer; then, the second material layer 102 is dry-etched based on the patterned mask layer, to form a through hole 111 in the second material layer 102; finally, the patterned mask layer is removed.

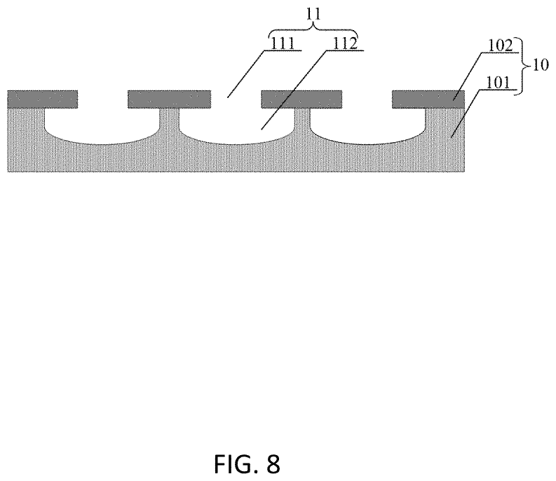

S114: the first material layer 101 is etched based on the through hole 111. Specifically, the first material layer 101 is etched based on the through hole 111 by a wet etching process to form a trench 112 in the first material layer 101, the width of the trench 112 is greater than the width of the through hole 111, the trench 112 interconnects with the through hole 111, and wherein the trench 112 and the through hole 111 jointly form the groove 11, as shown in FIG. 8.

In an example, the depth of the trench 112 can be less than the thickness of the first material layer 101, as shown in FIG. 8. At this point, the depth of the trench 112 can be set according to actual needs, for example, the depth of the trench 112 can be ⅓, ⅔, ¾, etc. of the thickness of the first material layer 101.

In an example, the width of the trench 112 may be 1.5 to 6 times the width of the through hole 111.

In another example, step S11 may include the following steps:

S111: forming a first material layer 101, as shown in FIG. 6; the first material layer 101 may be formed by a physical vapor deposition process, a chemical vapor deposition process, or an atomic layer deposition process; the first material layer 101 may include but is not limited to at least one of a silicon oxide layer, a silicon nitride layer, a silicon oxynitride layer, a silicon carbonitride layer, a tungsten layer, a titanium layer, a titanium nitride layer, and a tantalum layer.

S112: a second material layer 102 is formed on the upper surface of the first material layer 101, as shown in FIG. 6; the second material layer 102 may be formed by a physical vapor deposition process, a chemical vapor deposition process, or an atomic layer deposition process. The material layer 102 may include but is not limited to at least one of a silicon oxide layer, a silicon nitride layer, a silicon oxynitride layer, a silicon carbonitride layer, a tungsten layer, a titanium layer, a titanium nitride layer, and a tantalum layer.

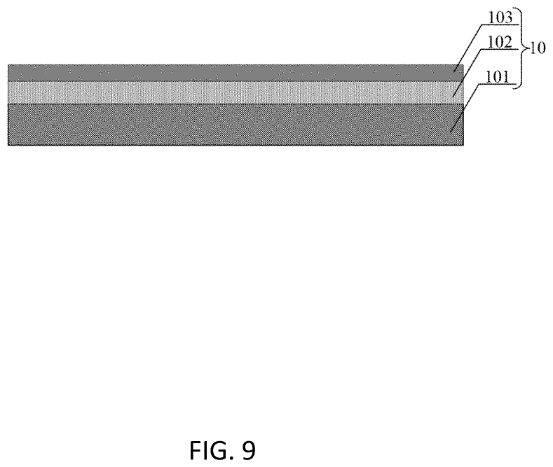

S113: a third material layer 103 is formed on the upper surface of the second material layer 102, as shown in FIG. 9; the third material layer 103 may include, but is not limited to, at least one of a silicon oxide layer, a silicon nitride layer, a silicon oxynitride layer, and a carbon nitride layer. silicon layer, tungsten layer, titanium layer, titanium nitride layer, and tantalum layer; it should be noted that the material of the second material layer 102 is different from the material of the first material layer 101, and under etching conditions, the third material layer 103 has a higher etching selection ratio than the second material layer 102 does, so as to ensure that the third material layer 103 can serve as an etching stop layer for the second material layer 102.

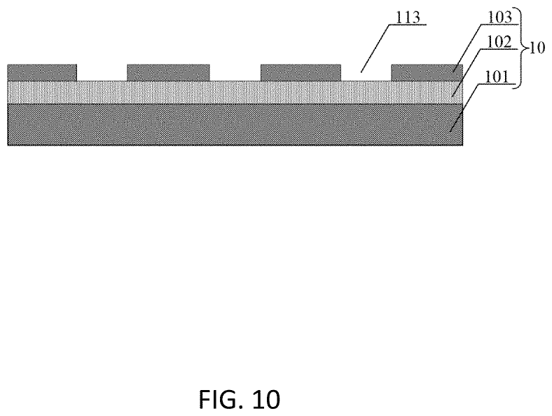

S114: the third material layer 103 is etched to form a first through hole 113 penetrating in the thickness direction of the third material layer 103, as shown in FIG. 10; specifically, first, a patterned mask layer (not shown) is formed on the upper surface of the layer 103. The patterned mask layer may include but is not limited to a patterned photoresist layer; then, the third material layer 103 is dried etched based on the patterned mask layer to form the first through hole 113 in the third material layer 103; finally, the patterned mask layer is removed.

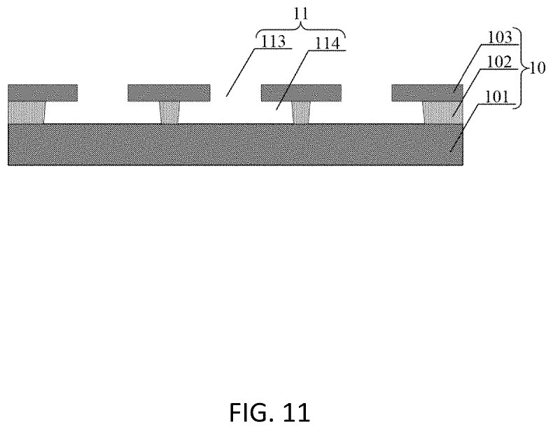

S115: The second material layer 102 is etched based on the first through hole 113. Specifically, the first material layer 101 is etched based on the through hole 111 by a wet etching process to form the second through hole 114 in the second material layer 102. The width of the second through hole 114 is greater than the width of the first through hole 113, the second through hole 114 connects to the first through hole 113, and forms the groove 11 together with the first through hole 113, such as shown in FIG. 11. In this embodiment, by providing the supporting layer 10 of the first material layer 101, the second material layer 102, and the third material layer 103, and making the first material layer 101 is used as the etching stop layer of the groove 11, the depth of groove 11 can be controlled.

In an example, the width of the second through hole 114 may be 1.5 to 6 times the width of the first through hole 113.

In an example, the shape of the opening of the groove 11 in each of the above examples may include, but is not limited to shapes like a rectangular bar, a cross, a circle, a star (a six-pointed star, a five-pointed star, etc.), and so on.

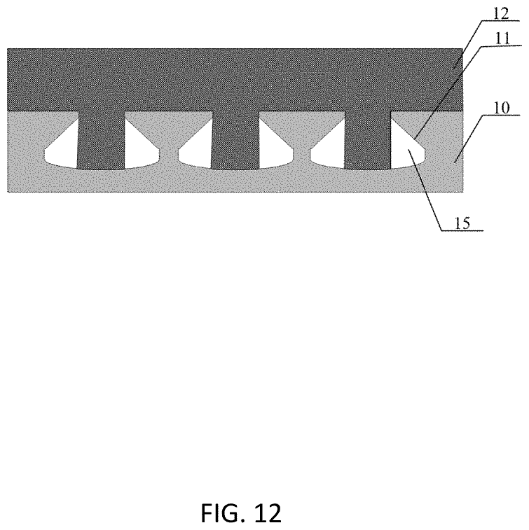

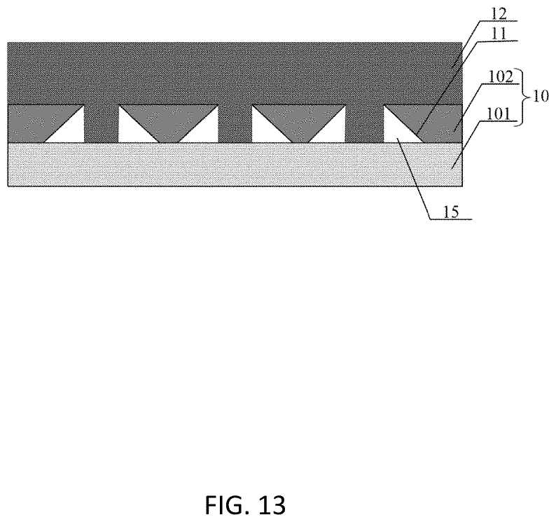

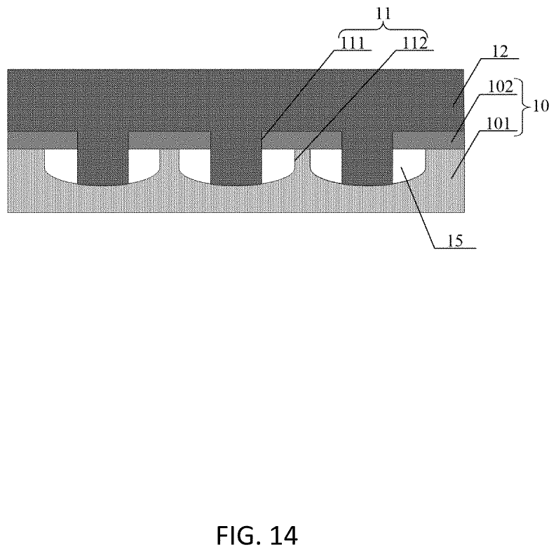

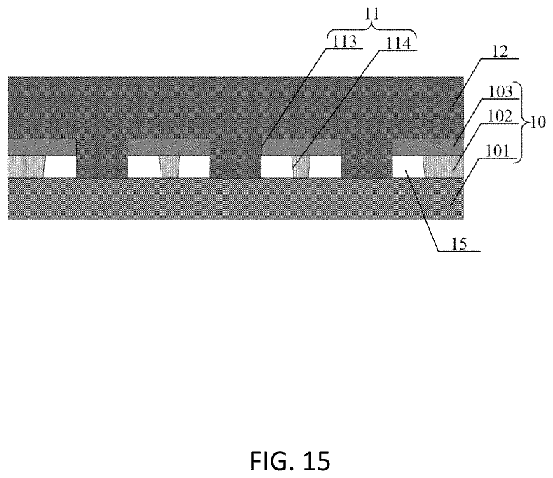

In an example, in step S12, as shown in FIGS. 12 to 15, the pad 12 may be formed by but not limited to electroplating and other processes; the pad 12 may include, but is not limited to, an aluminum solder pad. After the pad 12 is formed, there is a gap between the part of the pad 12 embedded in the groove 11 and the side wall of the lower part of the groove 11, that is, the part of the pad 12 embedded in the groove 11 and the side of the lower part of the groove 11. There is an air cavity 15 between the walls, as shown in FIGS. 12-15. When the air cavity 15 is used for the bonding wire 14 in the subsequent bonding process, the air cavity 15 can serve to accommodate the pad 12 when it is pushed out by the bonding wire 14, which can prevent the pushed out pad 12 from entering under the protective layer 13. The protective layer 13 is then prevented from being lifted up or cracked, and the pad 12 is prevented from overflowing out, thereby ensuring the quality of the product.

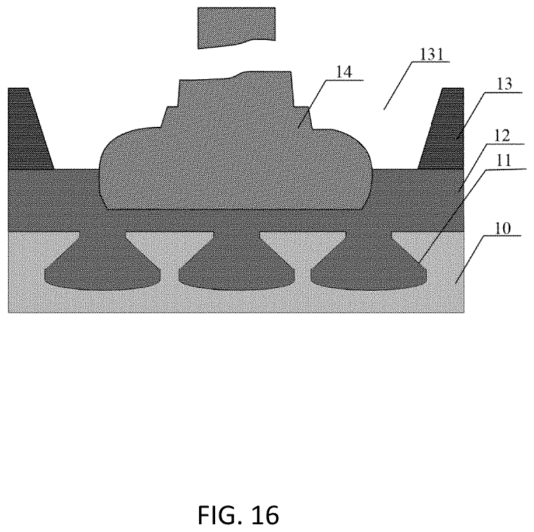

As shown in FIGS. 16-19, after step S12, the following steps are further included:

S13: forming a protective layer 13 on the upper surface of the supporting layer 10 and the upper surface of the pad 12, and the protective layer 13 covers the pad 12;

S14: forming an opening 131 in the protective layer 13, and the opening 131 exposes the pad 12;

S15: providing a bonding wire 14 and connecting one end of the bonding wire 14 to the pad 12.

In an example, the protective layer 13 may include, but is not limited to, a silicon oxide layer, a silicon nitride layer, a silicon oxynitride layer, or the like.

In an example, the bonding wire 14 may include, but is not limited to, a copper wire, an aluminum wire, a gold wire, or the like.

It should be noted that during the wire bonding process, the pad 12 may be squeezed out under the action of the bonding pressure, and the squeezed-out pad 12 will enter the air cavity 15, as shown in FIGS. 16 to 19. It is shown that the protective layer 13 can be prevented from being lifted up or cracked, and the pad 12 can be prevented from overflowing out, thereby ensuring the quality of the product.

In another embodiment, please continue to refer to FIGS. 16 to 19 in conjunction with FIGS. 2 to 15. The present application also provides a semiconductor structure, including: a supporting layer 10, which includes a pad area (not shown); and a groove 11 formed in the pad area of the supporting layer 10, wherein a bottom width of the groove 11 is greater than a top width of the groove 11; and

a pad 12 disposed in the pad area on the supporting layer 10, wherein the pad 12 is partially embedded in the groove 11.

In the above-mentioned semiconductor structure, a supporting layer with a plurality of grooves 11 is formed in the pad area under the pad 12, and the bottom width of the groove 11 is greater than the top width of the groove 11, and an air cavity is formed between part of the pad 12 in the embedded groove 11 and the side walls of the lower part of the groove 11. So even when the pad 12 is flat and most of the pad 12 will be squeezed out under the action of the bonding pressure during the wire bonding process, the pad 12 will enter the air cavity, which can prevent the protective layer from being lifted up or cracked, preventing the pad 12 from overflowing out, thereby ensuring the quality of the product. At the same time, the pad will enter the air cavity during the wire bonding process. This will increase the contact area between the pad 12 and the supporting layer 10, thereby enhancing the stability of the overall structure.

In an example, the supporting layer 10 may be formed on a substrate (not shown), and the substrate may be any substrate that can play a supporting role.

In an alternative example, as shown in FIG. 16, the supporting layer 10 may be a single-layer structure. The supporting layer 10 may include, but is not limited to, at least one of a silicon oxide layer, a silicon nitride layer, a silicon oxynitride layer, a silicon carbonitride layer, a tungsten layer, a titanium layer, a titanium nitride layer, and a tantalum layer.

In an example, the longitudinal cross-sectional shape of the groove 11 may be a bottle shape (as shown in FIG. 16), a trapezoid shape, or the like.

In an example, as shown in FIG. 16, the inclination angle α of the sidewall of the groove 11 with the upper surface of the supporting layer 10 may be 30°˜65°, specifically, it may be 30°, 40°, 50°, 60°, or 65° and so on. By limiting the inclination angle α of the sidewall of the groove 11 to the upper surface of the supporting layer 10 to be 30°˜65°, the pad 12 can fill the air cavity during the wire bonding process, so the contact area of the pad 12 with the supporting layer 10 is maximized, which provides the best overall structure stability.

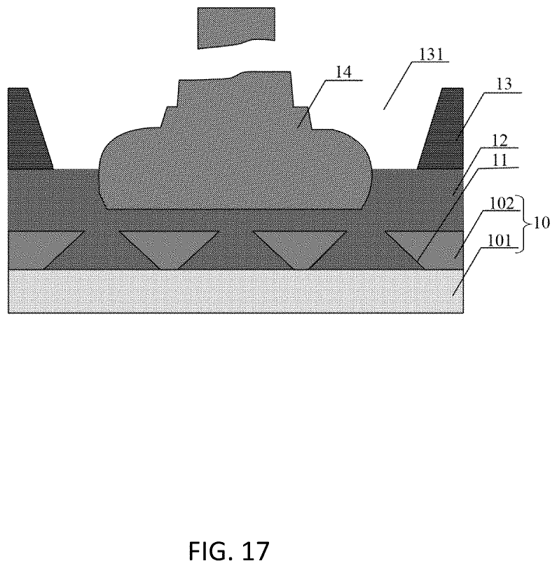

In another optional example, as shown in FIG. 17, the supporting layer 10 is a stacked structure, and the supporting layer 10 may include: a first material layer 101; a second material layer 102, the second material layer 102 is located on the upper surface of the layer 101; a groove 11 is formed in the second material layer 102.

In an example, the first material layer 101 may include at least one, but is not limited to, a silicon oxide layer, a silicon nitride layer, a silicon oxynitride layer, a silicon carbonitride layer, a tungsten layer, a titanium layer, a titanium nitride layer, and a tantalum layer. The second material layer 102 may include but is not limited to at least one of a silicon oxide layer, a silicon nitride layer, a silicon oxynitride layer, a silicon carbonitride layer, a tungsten layer, a titanium layer, a titanium nitride layer, and a tantalum layer. It should be noted that the material of the second material layer 102 is different from the material of the first material layer 101, and under the same etching conditions, the second material layer 102 has a higher etch selection value than the first material layer 101 does to ensure that the first material layer 101 can serve as an etch stop layer for the second material layer 102.

In an example, the depth of the groove 11 may be less than or equal to the thickness of the second material layer 102. Preferably, as shown in FIG. 17, the depth of the groove 11 is equal to the thickness of the second material layer 102.

In an example, the longitudinal cross-sectional shape of the groove 11 may be a bottle shape or a trapezoid shape (as shown in FIG. 17) and so on.

In an example, as shown in FIG. 17, the inclination angle α of the sidewall of the groove 11 compared to the upper surface of the supporting layer 10 may be 30°˜65°, specifically, it may be 30°, 40°, 50°, 60° or 65° and so on. By limiting the inclination angle α between the sidewall of the groove 11 and the upper surface of the supporting layer 10 to be in the range of 30°˜65°, the pad 12 can fill the air cavity during the wire bonding process, so that the contact area of the pad 12 with the supporting layer 10 is maximized, which provides the best stability of the overall structure.

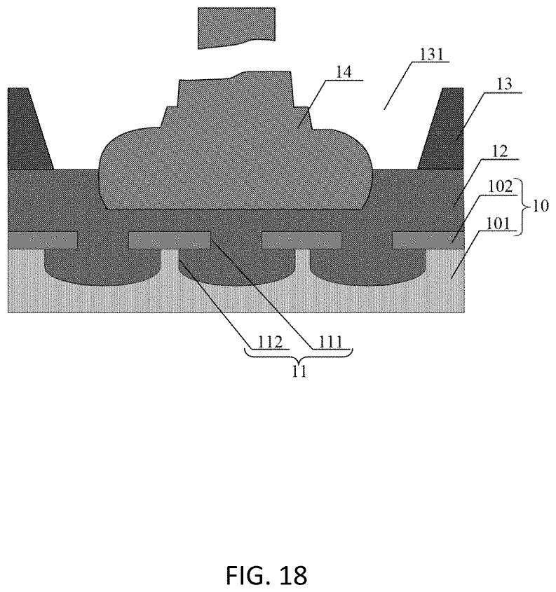

In yet another optional example, as shown in FIG. 18, the supporting layer 10 is a stacked structure, and the supporting layer 10 may include: a first material layer 101; a second material layer 102, the second material layer 102 is located on the upper surface of the first material layer 101; wherein the second material layer 102 is formed with a through hole 111 penetrating along its thickness direction, and the first material layer 101 is formed with a trench 112, the width of the trench 112 is greater than the width of the through hole 111, the trench 112 interconnects with the through hole 111, and wherein the trench 112 and the through hole 111 jointly form the groove 11.

In an example, the first material layer 101 may include, but is not limited to, at least one of a silicon oxide layer, a silicon nitride layer, a silicon oxynitride layer, a silicon carbonitride layer, a tungsten layer, a titanium layer, a titanium nitride layer, and a tantalum layer. The second material layer 102 may include but is not limited to at least of a silicon oxide layer, a silicon nitride layer, a silicon oxynitride layer, a silicon carbonitride layer, a tungsten layer, a titanium layer, a titanium nitride layer, and a tantalum layer. It should be noted that the material of the second material layer 102 is different from the material of the first material layer 101, and under the same etching conditions, the first material layer 101 has a higher etch selection ratio than the second material layer 102.

In an example, the depth of the trench 112 can be less than the thickness of the first material layer 101, as shown in FIG. 8. At this time, the depth of the trench 112 can be set according to actual needs, for example, the depth of the trench 112 can be ⅓, ⅔, ¾, etc. of the thickness of the first material layer 101.

In an example, the width of the trench 112 may be 1.5 to 6 times the width of the through hole 111.

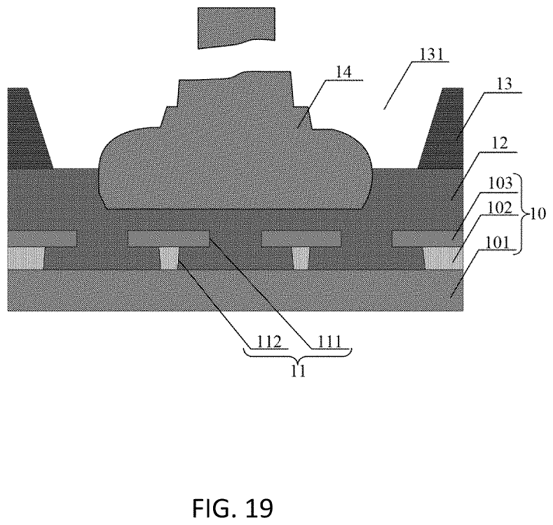

In yet another alternative example, as shown in FIG. 19, the supporting layer 10 is a stacked structure, and the supporting layer 10 may include: a first material layer 101; a second material layer 102, the second material layer 102 is located on the upper surface of the first material layer 101; the third material layer 103, the third material layer 103 is located on the upper surface of the second material layer 102; wherein the third material layer 103 is formed with a first through hole 113 penetrating in the thickness direction thereof, a second through hole 114 is formed in the second material layer 102 along its thickness direction; the width of the second through hole 114 is greater than the width of the first through hole 113, and the second through hole 114 interconnects with the first through hole 113, and wherein the first through hole 113 and the second through hole 114 jointly form a part of the groove 11.

In an example, the first material layer 101 may include, but is not limited to, at least one of a silicon oxide layer, a silicon nitride layer, a silicon oxynitride layer, a silicon carbonitride layer, a tungsten layer, a titanium layer, a titanium nitride layer, and a tantalum layer. The second material layer 102 may include but is not limited to at least a silicon oxide layer, a silicon nitride layer, a silicon oxynitride layer, a silicon carbonitride layer, a tungsten layer, a titanium layer, a titanium nitride layer, and a tantalum layer. The third material layer 103 may include but is not limited to at least one of a silicon oxide layer, a silicon nitride layer, a silicon oxynitride layer, a silicon carbonitride layer, a tungsten layer, a titanium layer, a titanium nitride layer, and a tantalum layer. It should be noted that the material of the second material layer 102 is different from the material of the first material layer 101, and under the same etching conditions, the third material layer 103 has a higher etch selection ratio than the second material layer 102 does. It ensures that the third material layer 103 serve as an etching stop layer for the second material layer 102.

In an example, the width of the second through hole 114 may be 1.5 to 6 times of the width of the first through hole 113.

In an example, the shape of the opening of the groove 11 in each of the above examples may include, but not limited to, a rectangular bar, a cross, a circle, a star (a six-pointed star, a five-pointed star, etc.), and so on.

In an example, please continue to refer to FIGS. 16 to 19, the semiconductor structure further includes: a protective layer 13 located on the upper surface of the supporting layer 10 and the pad 12; the protective layer 13 has an opening 131 which exposes the pad 12; the bonding wire 14, one end of the bonding wire 14 is located in the opening 131 and connected to the pad 12.

In an example, the protective layer 13 may include, but is not limited to, a silicon oxide layer, a silicon nitride layer, a silicon oxynitride layer, or the like.

In an example, the bonding wire 14 may include, but is not limited to, copper wire, aluminum wire, gold wire, or the like.

It should be noted that during the wire bonding process, the pad 12 will be squeezed out under the action of the bonding pressure, and the squeezed-out pad 12 will enter the air cavity 15, as shown in FIGS. 16 to 19. It is shown that the protective layer 13 can be prevented from being lifted up or cracked, and the pad 12 can be prevented from overflowing out, thereby ensuring the quality of the product.

The technical features of the above-mentioned embodiments can be combined arbitrarily. In order to make the description concise, all possible combinations of the technical features of the above-mentioned embodiments are not described. However, as long as there is no contradiction in the combination of these technical features, they should It is considered as the range described in this specification.

The above-mentioned embodiments only express several implementation manners of the present application, and the description is relatively specific and detailed, but it should not be understood as a limitation to the scope of the patent application. It should be pointed out that for those of ordinary skill in the art, without departing from the concept of this application, several modifications and improvements can be made, and these all fall within the protection scope of this application. Therefore, the scope of protection of the patent of this application shall be subject to the appended claims.

1. A semiconductor structure, comprising:
a supporting layer comprising a pad area; and a groove formed in the pad area of the supporting layer, wherein a bottom width of the groove is greater than a top width of the groove; and
a pad disposed in the pad area on the supporting layer, wherein the pad is partially embedded in the groove.

2. The semiconductor structure of claim 1, wherein the supporting layer is a single-layer structure.

3. The semiconductor structure of claim 1, wherein the supporting layer is a stacked structure comprising:
a first material layer; and
a second material layer disposed on an upper surface of the first material layer, wherein the groove is formed in the second material layer.

4. The semiconductor structure according to claim 1, wherein a longitudinal cross-section of the groove has a bottle shape or a trapezoid shape.

5. The semiconductor structure of claim 4, wherein an inclination angle between a sidewall of the groove and an upper surface of the supporting layer is in a range of 30° to 65°.

6. The semiconductor structure of claim 1, wherein the supporting layer is a stacked structure comprising:
a first material layer, wherein a trench is formed in the first material layer; and
a second material layer disposed on an upper surface of the first material layer, wherein a through hole penetrating in a thickness direction of the second material layer is formed in the second material layer, wherein a width of the trench is greater than a width of the through hole, wherein the trench interconnects with the through hole, and wherein the trench and the through hole jointly form the groove.

7. The semiconductor structure of claim 6, wherein the width of the trench is 1.5 to 6 times of the width of the through hole.

8. The semiconductor structure of claim 1, wherein the supporting layer is a stacked structure, comprising:
a first material layer;
a second material layer disposed on an upper surface of the first material layer; and
a third material layer disposed on an upper surface of the second material layer;
wherein a first through hole penetrating in a thickness direction of the third material layer is formed in the third material layer, a second through hole penetrating in the thickness direction of the second material layer is formed in the second material layer; wherein a width of the second through hole is greater than a width of the first through hole, wherein the second through hole interconnects with the first through hole, and wherein the first through hole and the second through hole jointly form a part of the groove.

9. The semiconductor structure of claim 8, wherein the width of the second through hole is 1.5 to 6 times of the width of the first through hole.

10. The semiconductor structure of claim 1, wherein the semiconductor structure further comprises:
a protective layer disposed on an upper surface of the supporting layer and an upper surface of the pad, wherein the protective layer has an opening exposing the pad; and
a bonding wire, wherein one end of the bonding wire is disposed in the opening and wherein the bonding wire is connected with the pad.

11. A method for manufacturing a semiconductor structure, comprising following steps:
forming a supporting layer, wherein the supporting layer comprises a pad area, and wherein a groove is formed in the pad area of the supporting layer, and wherein a bottom width of the groove is greater than a top width of the groove; and
forming a pad in the pad area of the supporting layer, wherein the pad is partially embedded in the groove.

12. The method for manufacturing the semiconductor structure according to claim 11, wherein forming the supporting layer comprises following steps:
forming a material layer; and
etching the material layer to form the groove.

13. The method for manufacturing the semiconductor structure according to claim 11, wherein forming the supporting layer comprises following steps:
forming a first material layer;
forming a second material layer on an upper surface of the first material layer; and
etching the second material layer to form the groove.

14. The method for manufacturing the semiconductor structure according to claim 11, wherein forming the supporting layer comprises following steps:
forming a first material layer;
forming a second material layer on an upper surface of the first material layer;
etching the second material layer to form a through hole which penetrates in a thickness direction of the second material layer; and
etching the first material layer from the through hole to form a trench, wherein a width of the trench is greater than a width of the through hole, wherein the trench interconnects with the through hole, and wherein the trench and the through hole jointly form the groove.

15. The method for manufacturing the semiconductor structure according to claim 11, wherein forming the supporting layer comprises following steps:
forming a first material layer;
forming a second material layer on an upper surface of the first material layer;
forming a third material layer on an upper surface of the second material layer;
etching the third material layer to form a first through hole penetrating the third material layer in a thickness direction; and
etching the second material layer from the first through hole to form a second through hole penetrating the second material layer in a thickness direction, wherein a width of the second through hole is greater than a width of the first through hole, wherein the second through hole interconnects with the first through hole, and wherein the first through hole and the second through hole jointly form the groove.

16. The method for manufacturing the semiconductor structure according to claim 11, further comprising following steps, after forming the pad:
forming a protective layer on an upper surface of the supporting layer and an upper surface of the pad, wherein the protective layer covers the pad;
forming an opening in the protective layer, wherein the opening exposes the pad;
providing a bonding wire; and
connecting one end of the bonding wire with the pad.
